(19) United States
(12) Patent Application Publication
(10) Pub. No.: US 2026/0089848 A1
(43) Pub. Date: Mar. 26, 2026

(54) METHOD FOR MANUFACTURING WIRING SUBSTRATE

(71) Applicant: IBIDEN CO., LTD., Gifu (JP)

(72) Inventors: Ayami OHNO, Gifu (JP); Toshihide MAKINO, Gifu (JP)

(73) Assignee: IBIDEN CO., LTD., Gifu (JP)

(21) Appl. No.: 19/338,452

(22) Filed: Sep. 24, 2025

(30) Foreign Application Priority Data
Sep. 25, 2024 (JP) 2024-166518

(51) Int. Cl. H05K 3/40

(52) U.S. Cl. CPC H05K 3/4038

(57) ABSTRACT

A method for manufacturing a wiring substrate includes preparing a support substrate having a metal film layer, forming a plating film layer including an alignment pattern on the metal film layer, forming an insulating layer such that the insulating layer covers the plating film layer, irradiating the insulating layer with laser based on position information obtained from the alignment pattern in the plating film such that a through hole penetrating through the insulating layer is formed, and filling the through hole formed in the insulating layer with conductor such that a via conductor is formed in the insulating layer. The forming of the plating film layer includes causing specular reflectance of light of a predetermined wavelength at an upper surface of the metal film layer formed on the support substrate to differ from specular reflectance of light of the predetermined wavelength at an upper surface of the plating film layer.

### CROSS-REFERENCE TO RELATED APPLICATIONS

The present application is based upon and claims the benefit of priority to Japanese Patent Application No. 2024-166518, filed Sep. 25, 2024, the entire contents of which are incorporated herein by reference.

### BACKGROUND OF THE INVENTION

### Field of the Invention

The present invention relates to a method for manufacturing a wiring substrate.

### Description of Background Art

Japanese Patent Laid-Open Publication No. 2012-9606 describes a method for manufacturing a wiring substrate. The entire contents of this publication are incorporated herein by reference.

### SUMMARY OF THE INVENTION

According to one aspect of the present invention, a method for manufacturing a wiring substrate includes preparing a support substrate having a metal film layer formed on a surface thereof, forming a plating film layer including an alignment pattern on the metal film layer formed on the support substrate, forming an insulating layer such that the insulating layer covers the plating film layer formed on the metal film layer, irradiating the insulating layer with laser based on position information obtained from the alignment pattern in the plating film such that a through hole penetrating through the insulating layer is formed, and filling the through hole formed in the insulating layer with a conductor such that a via conductor is formed in the insulating layer. The forming of the plating film layer includes causing a specular reflectance of light of a predetermined wavelength at an upper surface of the metal film layer formed on the support substrate to differ from a specular reflectance of light of the predetermined wavelength at an upper surface of the plating film layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate manufactured using a manufacturing method according to an embodiment of the present invention;

FIG. 2 is a cross-sectional view illustrating another example of a wiring substrate manufactured using a manufacturing method according to an embodiment of the present invention;

FIG. 3A illustrates an example of a manufacturing method according to an embodiment of the present invention;

FIG. 3B illustrates an example of a manufacturing method according to an embodiment of the present invention;

FIG. 3C illustrates an example of a manufacturing method according to an embodiment of the present invention;

FIG. 3D illustrates an example of an example of a manufacturing method according to an embodiment of the present invention;

FIG. 3E illustrates an example of an example of a manufacturing method according to an embodiment of the present invention;

FIG. 3F illustrates an example of an example of a manufacturing method according to an embodiment of the present invention;

FIG. 3G illustrates an example of an example of a manufacturing method according to an embodiment of the present invention;

FIG. 3H illustrates an example of an example of a manufacturing method according to an embodiment of the present invention;

FIG. 3I illustrates an example of an example of a manufacturing method according to an embodiment of the present invention;

FIG. 3J illustrates an example of an example of a manufacturing method according to an embodiment of the present invention;

FIG. 3K illustrates an example of an example of a manufacturing method according to an embodiment of the present invention;

FIG. 3L illustrates an example of an example of a manufacturing method according to an embodiment of the present invention;

FIG. 3M illustrates an example of an example of a manufacturing method according to an embodiment of the present invention;

FIG. 3N illustrates an example of an example of a manufacturing method according to an embodiment of the present invention;

FIG. 30 illustrates an example of an example of a manufacturing method according to an embodiment of the present invention;

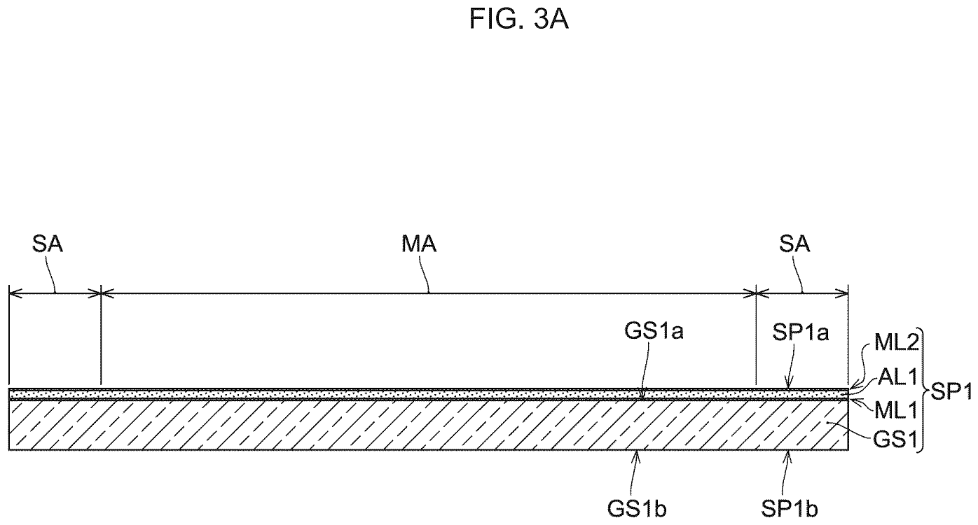

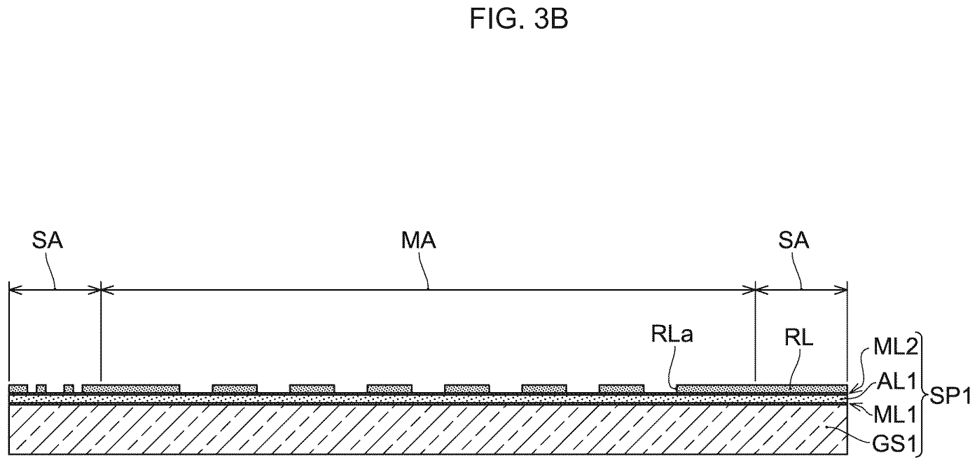

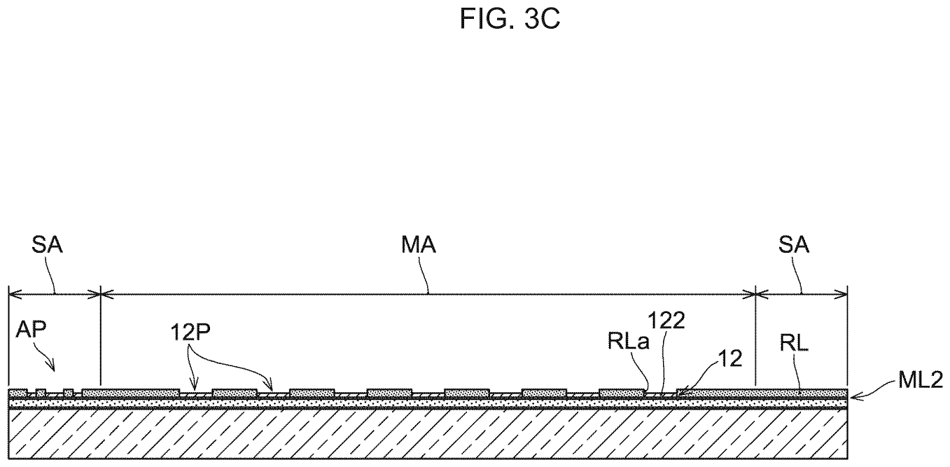

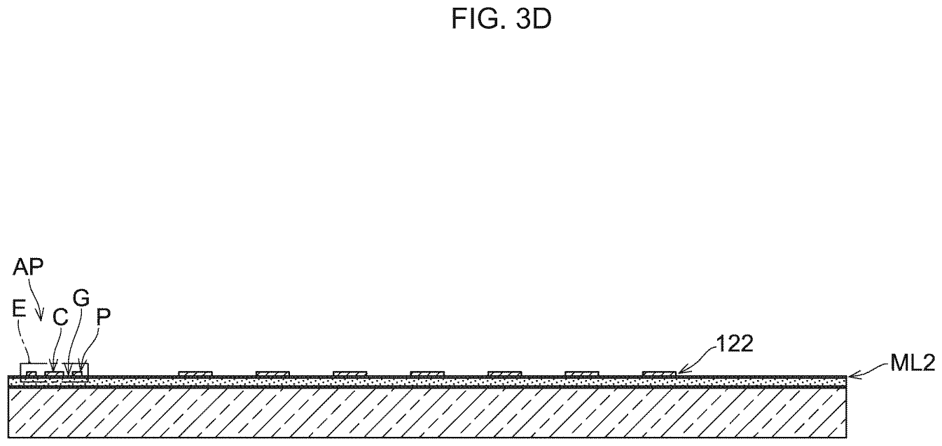

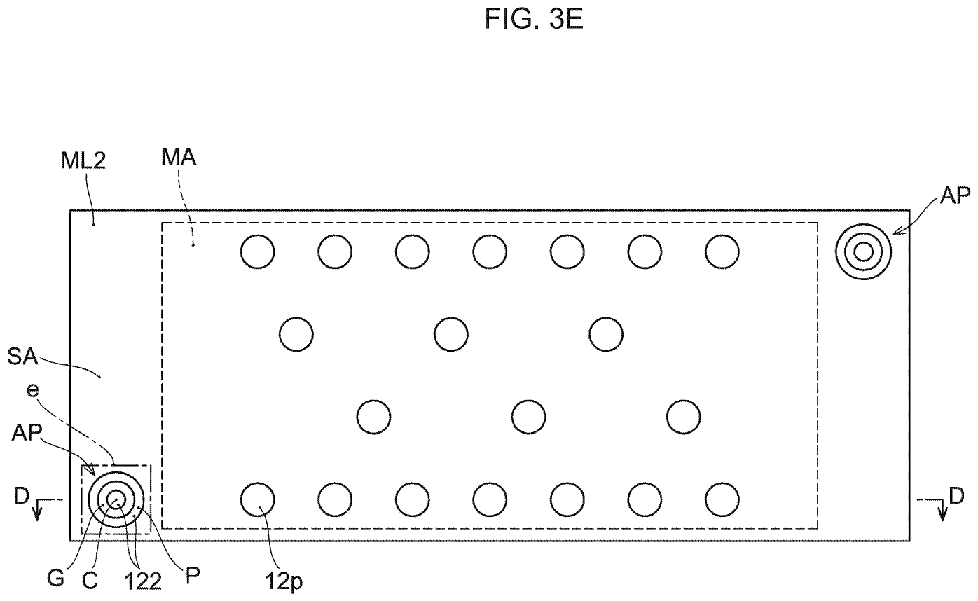

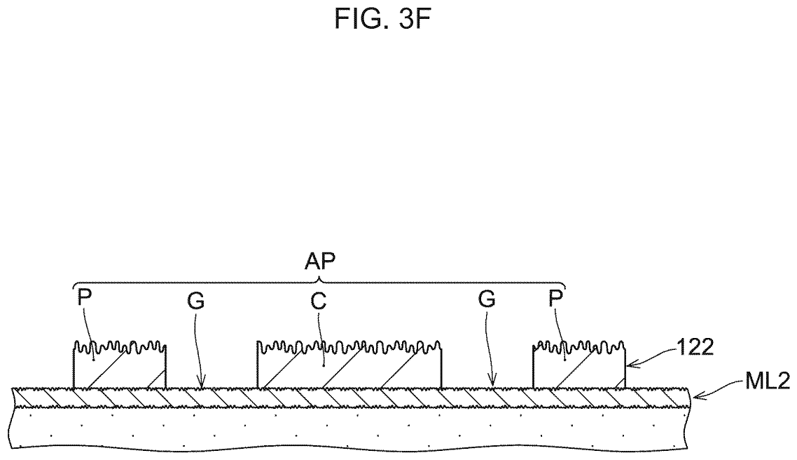

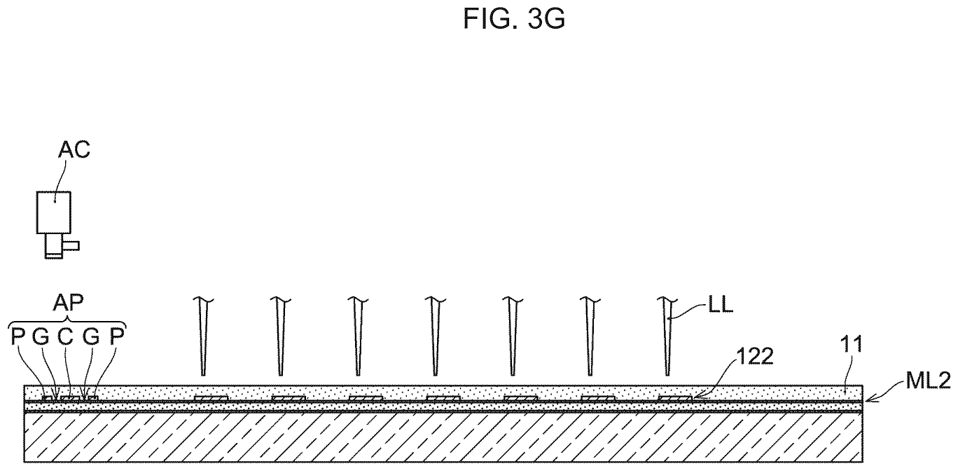

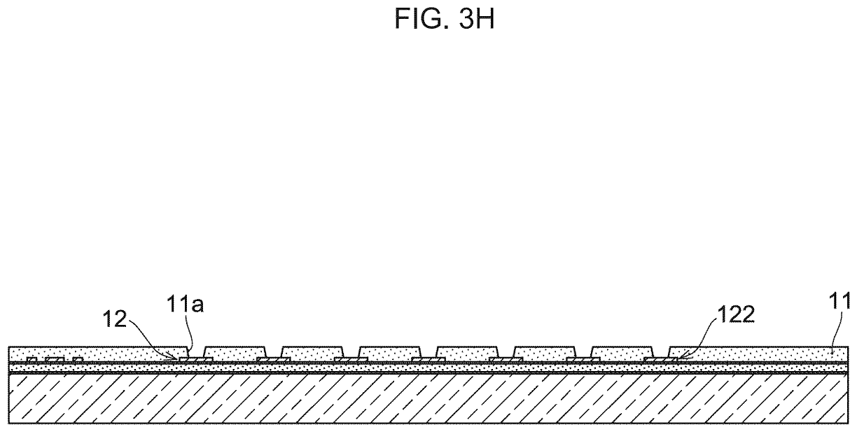

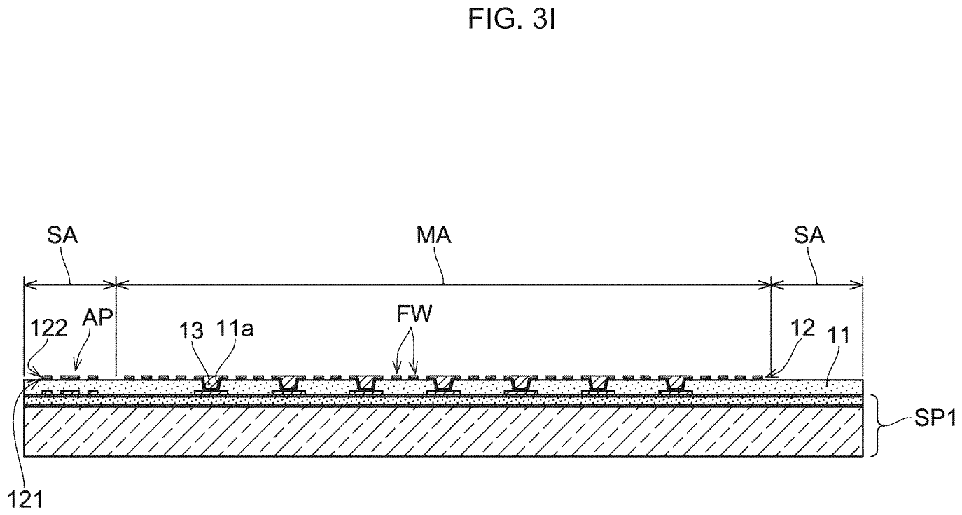

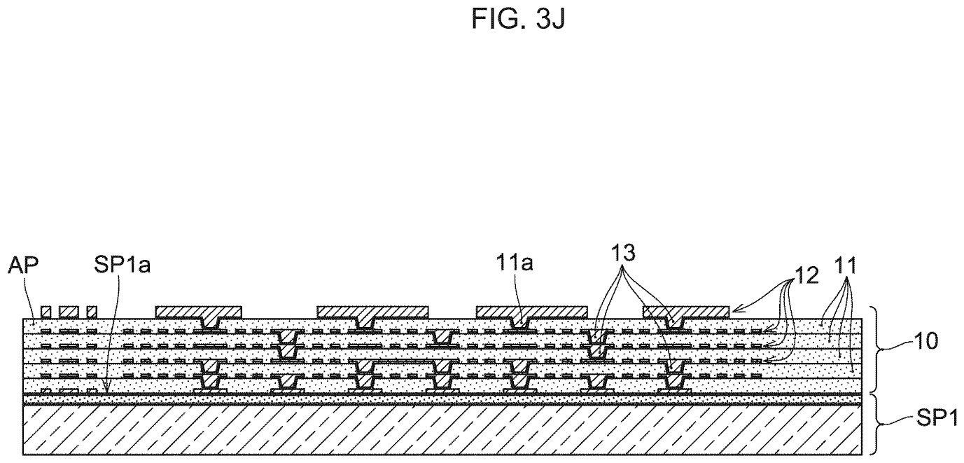

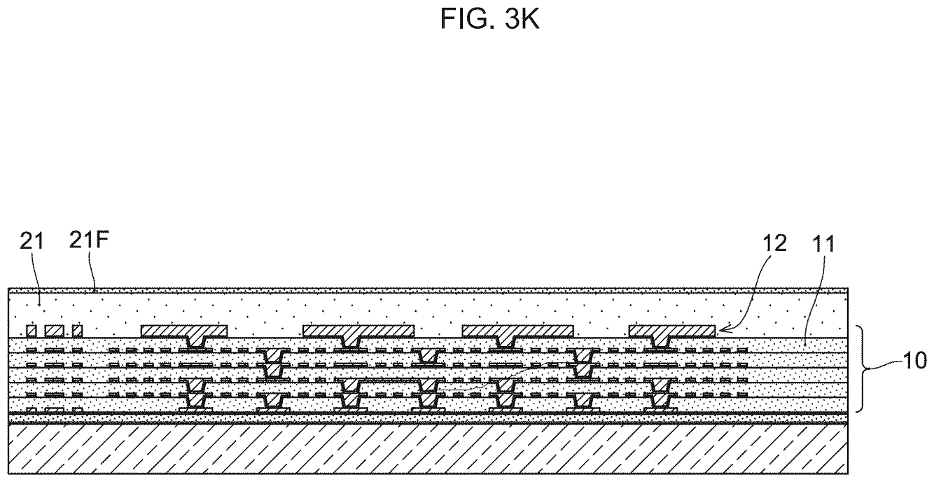

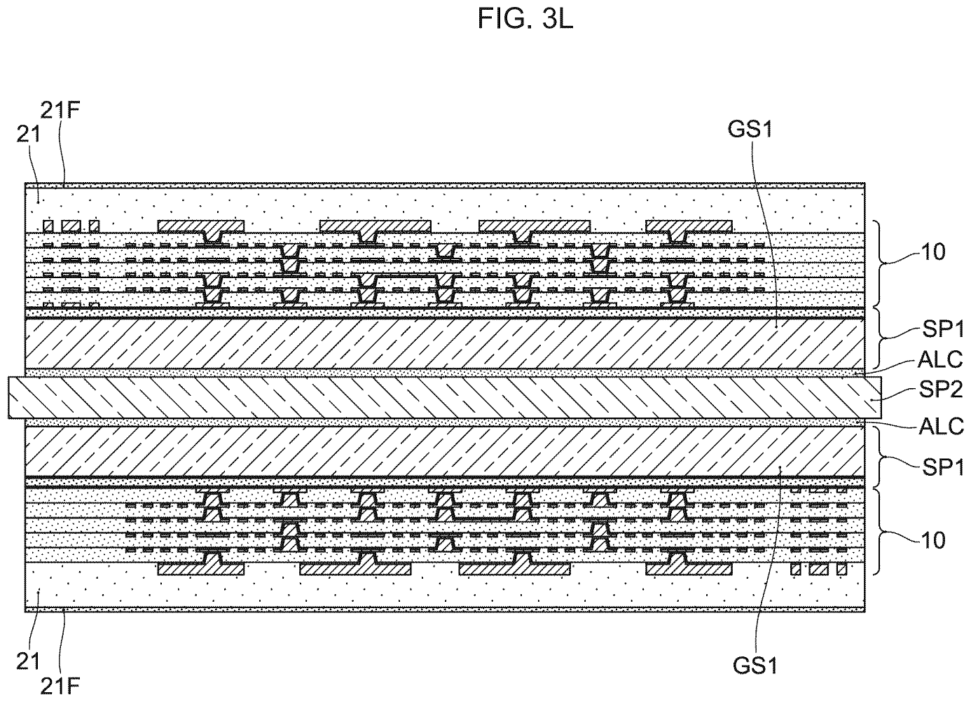

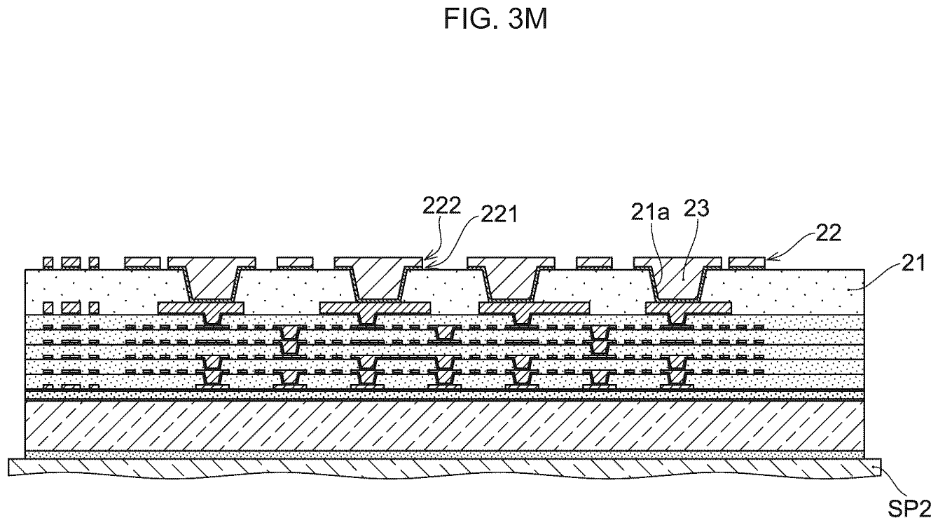

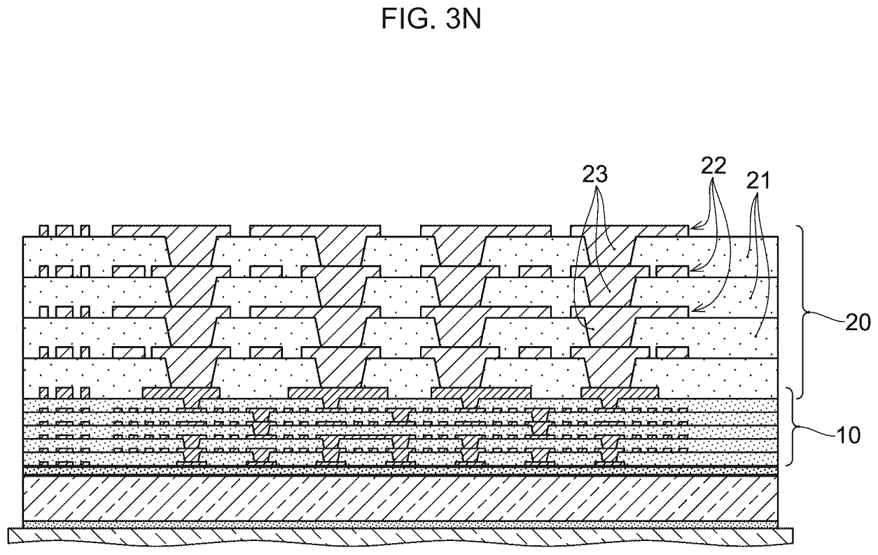

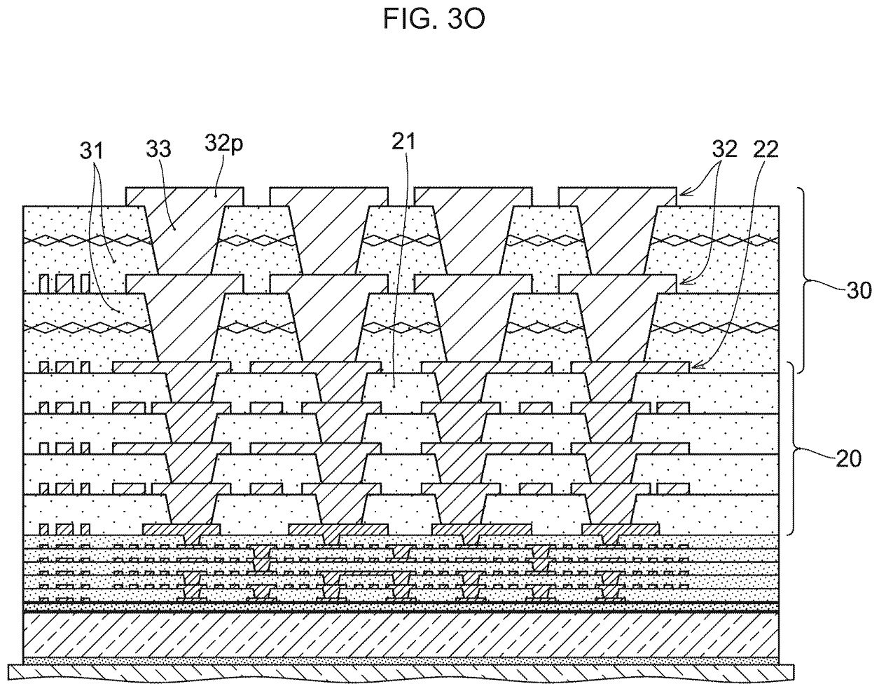

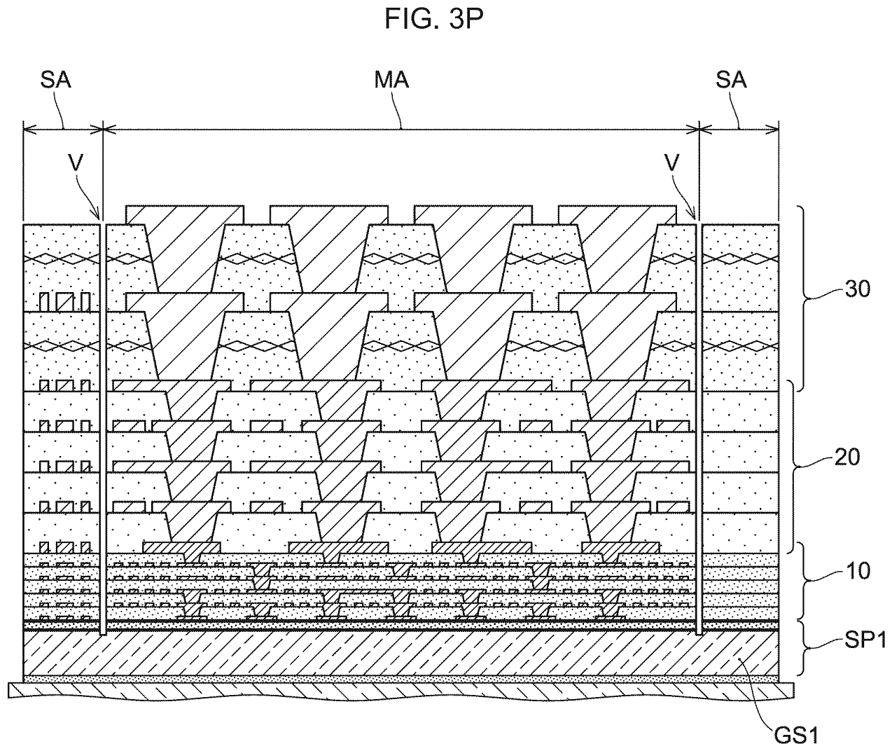

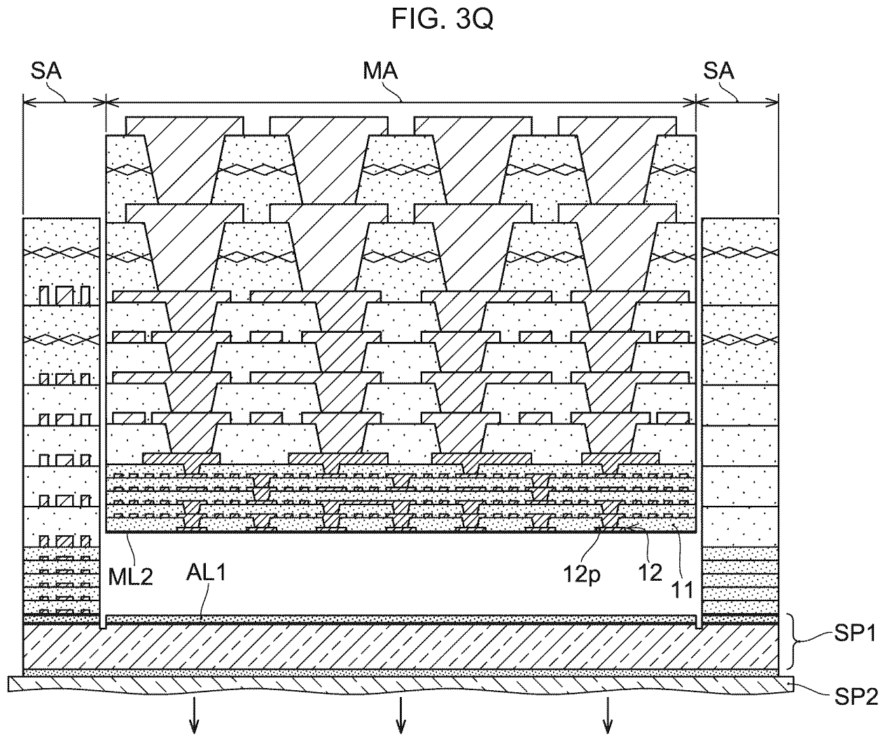

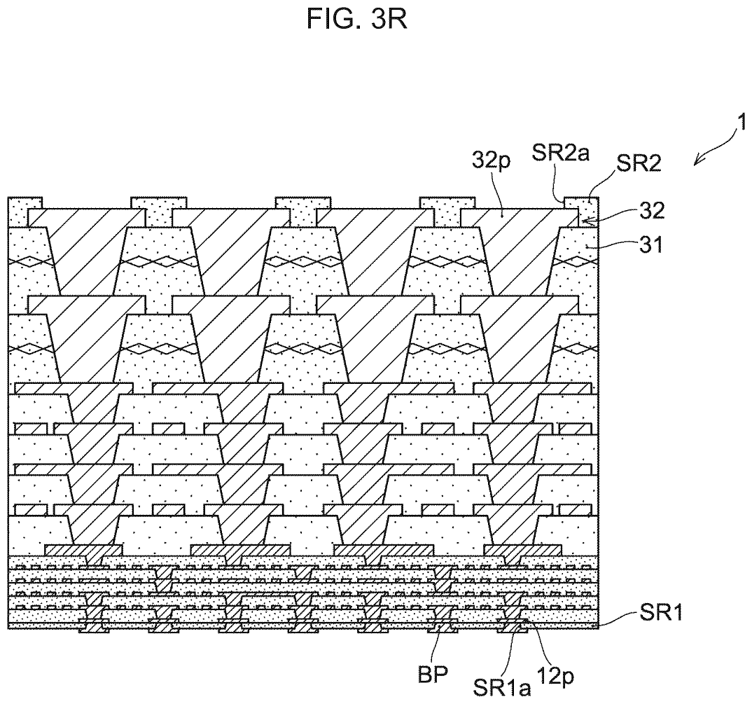

FIG. 3P illustrates an example of an example of a manufacturing method according to an embodiment of the present invention;

FIG. 3Q illustrates an example of an example of a manufacturing method according to an embodiment of the present invention; and

FIG. 3R illustrates an example of an example of a manufacturing method according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

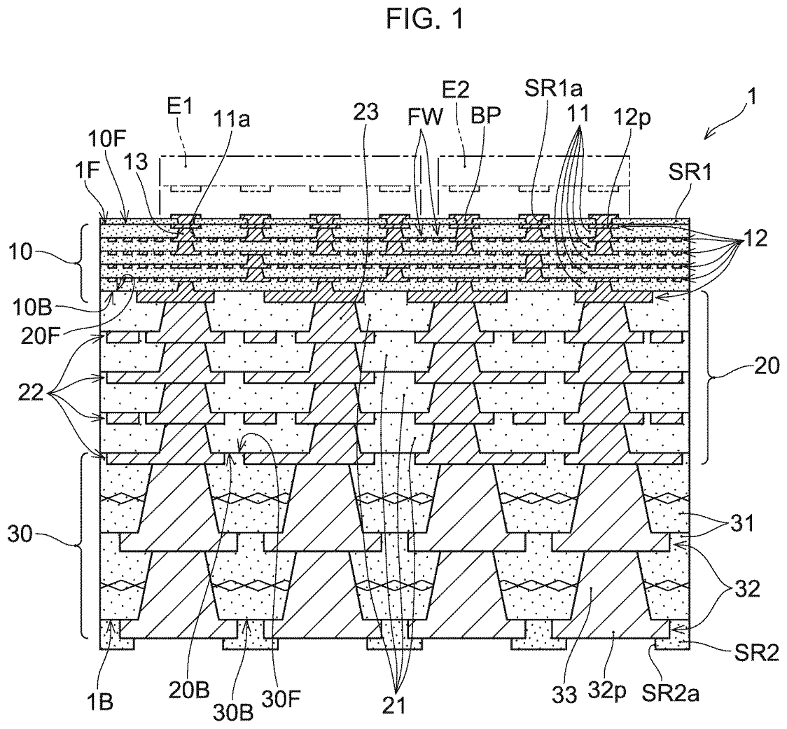

FIG. 1 is a cross-sectional view illustrating a wiring substrate 1, which is an example of a wiring substrate manufactured using a method for manufacturing a wiring substrate according to an embodiment of the present invention. A laminated structure, as well as the number of conductor layers and insulating layers, of a wiring substrate to be manufactured are not limited to the laminated structure of the wiring substrate 1 of FIG. 1, and the number of conductor layers and insulating layers included in the wiring substrate 1. The wiring substrate 1 has a laminated structure that includes a build-up part, which is formed of alternately laminated multiple conductor layers and insulating layers.

The build-up part constituting the wiring substrate 1 has two surfaces (a first surface (1F) and a second surface (1B) on the opposite side with respect to the first surface (1F)) orthogonal to a thickness direction thereof. A surface of a first build-up part 10 constitutes the first surface (1F). A surface of a third build-up part 30 constitutes the second surface (1B).

The wiring substrate 1 illustrated in FIG. 1 further includes, on a second surface (10B) side of the first build-up part 10, a second build-up part 20 and a third build-up part 30, each composed of alternately laminated insulating layers and conductor layers.

In the description of the wiring substrate 1 of the present embodiment illustrated in FIG. 1, a first surface (10F) side of the first build-up part 10, that is, the first surface (1F) side of the wiring substrate 1, is referred to as “upper” or an “upper side,” and the second surface (1B) side of the wiring substrate 1 is referred to as “lower” or a “lower side.” Further, for each of the structural elements, a surface facing the first surface (1F) side of the wiring substrate 1 is also referred to as an “upper surface,” and a surface facing the second surface (1B) side of the wiring substrate 1 is also referred to as a “lower surface.”

In the illustrated example, the first build-up part 10, the second build-up part 20, and the third build-up part 30 each include multiple insulating layers and multiple conductor layers. As illustrated in the drawing, the first build-up part 10 includes alternately laminated insulating layers (first insulating layers) 11 and conductor layers (first conductor layers) 12. Conductor layers facing each other with one insulating layer 11 in between are connected by via conductors (first via conductors) 13. The second build-up part 20 includes alternately laminated insulating layers (second insulating layers) 21 and conductor layers (second conductor layers) 22. Conductor layers facing each other with one insulating layer 21 in between are connected by via conductors (second via conductors) 23. The third build-up part 30 includes alternately laminated insulating layers (third insulating layers) 31 and conductor layers (third conductor layers) 32. Conductor layers facing each other with one insulating layer 31 in between are connected by via conductors (third via conductors) 33.

The conductor layers (12, 22, 32) are each patterned to have predetermined conductor patterns. In the illustrated example, the first conductor layer 12 constituting the first surface (10F) is formed to have patterns including multiple conductor pads (12p). As illustrated, a solder resist layer (SR1) formed using, for example, a photosensitive polyimide resin or epoxy resin is laminated on the first surface (10F). Openings (SR1a) are formed in the solder resist layer (SR1), and conductive bumps (BP) are formed on the conductive pads (12p) exposed in the openings (SR1a). As illustrated in the example of FIG. 1, the first surface (1F) of the wiring substrate 1 is a component mounting surface on which, for example, electronic components (E1, E2) that are active components such as a semiconductor integrated circuit device or a transistor are mounted, and the conductor pads (12p) can be connected to the electronic components (E1, E2) via the conductor bumps (BP). Specifically, for example, the electronic components (E1, E2) can each be an integrated circuit such as a logic chip incorporating a logic circuit, a processing unit such as an MPU (Micro Processor Unit), or a memory element such as an HBM (High Bandwidth Memory).

In the illustrated example, the wiring substrate 1 further includes a solder resist layer (SR2) formed on the second surface (1B), which is constituted by the surfaces of the insulating layer 31 and the conductor layer 32. The solder resist layer (SR2) is formed, for example, using a photosensitive polyimide resin or epoxy resin. Openings (SR2a) are formed in the solder resist layer (SR2), and conductor pads (32p) of the conductor layer 32 of the third build-up part 30 are exposed from the openings (SR2a). The second surface (1B) of the wiring substrate 1 on the opposite side with respect to the component mounting surface of the wiring substrate 1 can be a connection surface that is to be connected to an external element such as an external wiring substrate (for example, a motherboard of any electrical device) when the wiring substrate 1 itself is mounted on the external element. The conductor pads (32p) can be connected to any substrate, electrical component, mechanism component, or the like.

The first insulating layers 11 of the first build-up part 10 can be formed, for example, using an insulating resin such as an epoxy resin or a phenol resin. The insulating layers 11 may contain one of a fluorine resin, a liquid crystal polymer (LCP), a fluoroethylene resin (PTFE), a polyester resin (PE), and a modified polyimide resin (MPI).

Examples of conductors forming the first conductor layers 12 and the first via conductors 13 of the first build-up part 10 include copper, nickel, and the like, and copper is preferably used. In FIG. 1, for ease of viewing, the conductor layers 12 and the via conductors 13 are each illustrated as having a single-layer structure. However, the conductor layers 12 and the via conductors 13 can each have a multilayer structure. For example, the conductor layers 12 and the via conductors 13 can each have a two-layer structure including a metal film layer (for example, a sputtering film layer or an electroless plating film layer) and a plating film layer (for example, an electrolytic plating film layer).

The second insulating layers 21 of the second build-up part 20 and the third insulating layers 31 of the third build-up part 30 can be formed using an insulating resin similar to that used for the first insulating layers 11. The insulating layers (11, 21, 31) in the respective build-up parts may contain the same insulating resin or mutually different insulating resins. The insulating layers (21, 31) may each contain a core material (reinforcing material) formed of a glass fiber or an aramid fiber.

Similar to the first conductor layers 12 and the first via conductors 13, the second conductor layers 22 of the second build-up part 20 and the third conductor layers 32 of the third build-up part 30, as well as the via conductors (23, 33), can be formed using any metal such as copper or nickel. The conductor layers (22, 32) are each patterned to have predetermined conductor patterns. The conductor layers (22, 32) and the via conductors (23, 33) may each have a multilayer structure, for example, a two-layer structure including a metal film layer and a plating film layer.

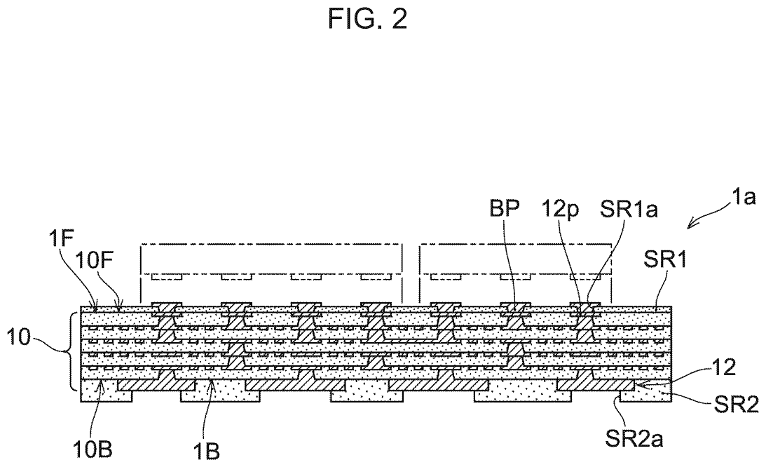

FIG. 2 illustrates a wiring substrate (1a) as another example of a wiring substrate manufactured using the manufacturing method of the embodiment. The wiring substrate (1a) includes a first build-up part 10 having a first surface (10F) and a second surface (10B), a solder resist layer (SR1) covering the first surface (10F), and a solder resist layer (SR2) covering the second surface (10B). Conductor pads (12p) are exposed in openings (SR1a) formed in the solder resist layer (SR1), and conductive bumps (BP) are formed on the conductive pads (12p). The lowermost conductor layer 12 is exposed in openings (SR2a) formed in the solder resist layer (SR2). When a wiring substrate manufactured using the method for manufacturing a wiring substrate of the embodiment does not include any build-up parts other than the first build-up part 10, it can have the form of the wiring substrate (1a) as illustrated. The above-described wiring substrates (1, 1a) each have, for example, a rectangular shape with each side measuring 80 mm or more and less than 240 mm in plan view. Here, the term “plan view” means viewing an object along the thickness direction of the wiring substrate 1.

Next, with reference to FIGS. 3A-3R , a method for manufacturing a wiring substrate of the embodiment is described using a case where the wiring substrate 1 illustrated in FIG. 1 is manufactured as an example. Structural elements formed in the manufacturing method to be described below can be formed using the materials exemplified as the materials of the corresponding structural elements in the description of the wiring substrate 1 in FIG. 1, unless otherwise specified. In the following description about the method for manufacturing the wiring structure 1, a side closer to a core material (GS1) constituting a first support substrate (SP1), on which the first build-up part 10 is formed, is referred to as “lower” or a “lower side,” and a side farther from the core material (GS1) is referred to as “upper” or an “upper side.” Therefore, of each of the elements constituting the wiring structure 1, a surface facing the first support substrate (SP1) is referred to as a “lower surface,” and a surface facing the opposite side with respect to the first support substrate (SP1) is also referred to as an “upper surface.”

First, as illustrated in FIG. 3A, the first support substrate (SP1) is prepared. The first support substrate (SP1) has, as two surfaces orthogonal to its thickness direction, a first surface (SP1a) and a second surface (SP1b) on the opposite side with respect to the first surface (SP1a). The first support substrate (SP1) includes a core material (GS1) having a surface (GS1a) on one side and another surface (GS1b) on the opposite side with respect to the surface (GS1a). The core material (GS1) can be, for example, a glass substrate, a ceramic substrate, or a silicon substrate. The first support substrate (SP1) includes, in addition to the core material (GS1), a first metal film layer (ML1) laminated on the surface (GS1a) of the core material (GS1), and a second metal film layer (ML2) laminated on the first metal film layer (ML1) via an adhesive layer (AL1). The first and second metal film layers (ML1, ML2) are metal film layers formed by, for example, electroless plating or sputtering. In the illustration, the first and second metal film layers (ML1, ML2) are each depicted as a single layer, but they may each include multiple layers. For example, the first and second metal film layers (ML1, ML2) can each have a two-layer structure (not illustrated) including a titanium layer and a copper layer. In this case, the copper layer is formed on an outer side of the titanium layer in each of the first and second metal film layers (ML1, ML2). Therefore, in this case, the first surface (SP1a) of the first support substrate (SP1) is constituted by a surface of the copper layer of the second metal film layer (ML2).

In the following, in FIG. 3A as well as in FIGS. 3B to 3R, an example is described in which the first surface (SP1a) of the first support substrate (SP1) includes one product area (MA), and one wiring substrate is formed in this one product area (MA). However, it is also possible that the first support substrate includes one or multiple product areas (MA) in each of which one wiring substrate is formed. When the first surface (SP1a) of the first support substrate (SP1) includes multiple product areas (MA), wiring substrates are manufactured by dividing a laminate formed continuously across the multiple product areas (MA) for each product area (MA). For example, each product area (MA) on the first surface (SP1a) of the first support substrate (SP1) has a rectangular shape with each side measuring 80 mm or more and 240 mm or less in a plan view. Therefore, a laminate (build-up part) constituting wiring substrates, formed across one or multiple product areas (MA) on the first surface (SP1a) of the first support substrate (SP1), can have at least a rectangular shape with each side measuring 80 mm or more and 240 mm or less in a plan view. As illustrated, in addition to the product area (MA), the first surface (SP1a) of the support substrate (SP1) has a peripheral area (SA) positioned around the product area (MA). In the peripheral area (SA), as will be described later with reference to FIGS. 3B to 3H, an alignment pattern is formed that serves as a reference for position information referenced during a manufacturing process of the wiring substrate 1.

Next, with reference to FIGS. 3B to 3J, the formation of the first build-up part 10 (FIG. 1) on the first support substrate (SP1) is described. The first build-up part 10 is formed only on the upper side of the first surface (SP1a) of the first support substrate (SP1).

As illustrated in FIG. 3B, a resist layer (RL) having openings (RLa) is formed on a surface of the metal film layer (ML2), which constitutes the first surface (SP1a) of the first support substrate (SP1). First, for example, a dry film resist containing a photosensitive epoxy resin is adhered onto the upper surface of the metal film layer (ML2), and the resist layer (RL) is formed. Subsequently, the resist layer (RL) is subjected to exposure. In the process of exposing the resist layer (RL), direct imaging exposure with relatively high resolution can be performed. In the direct imaging exposure, no photomask is used, and exposure light is directly irradiated onto the resist layer (RL). Exposure light is scanned according to drawing patterns corresponding to the conductor patterns of the first conductor layer 12 to be formed on the metal film layer (ML2) (see FIG. 3D). Subsequently, the resist layer (RL) is developed with a developer. By the development, the resist layer (RL) is formed that has the openings (RLa) corresponding to the conductor pads (12p) in the product area (MA), which are the conductor patterns of the first conductor layer 12 to be formed on the metal film layer (ML1), and the alignment pattern (AP) in the peripheral area (SA) (see FIG. 3D).

Next, as illustrated in FIG. 3C, a plating film layer 122 that constitutes the first conductor layer 12 is formed in the openings (RLa) by electrolytic plating using the metal film layer (ML2) as a power feeding layer. The plating film layer 122 that constitutes the conductor pads (12p) to be formed is formed in the openings (RLa) located in the product area (MA), and the plating film layer 122 that constitutes the alignment pattern (AP) to be formed is formed in the openings (RLa) located in the peripheral area (SA). The plating film layer 122 is formed to have a thickness (shortest distance between the upper surface of the metal film layer (ML2) and the upper surface of the plating film layer 122), for example, of 3 μm or more and 6 μm or less. The plating film layer 122 can be formed from the same material (for example, copper) as the material constituting the metal film layer (ML2).

Subsequently, the upper surface of the plating film layer 122 is subjected to a roughening treatment. For example, the upper surface of the plating film layer 122 is roughened by a wet etching treatment using a chemical solution such as a permanganate solution, or by a dry etching treatment using a plasma gas such as oxygen plasma. Specifically, as will be described later with reference to FIG. 3G, the upper surface of the plating film layer 122 is roughened so that the specular reflectance of light of a predetermined wavelength that can be detected by a device that images the alignment patterns (AP) differs between the upper surface of the plating film layer 122 and the upper surface of the metal film layer (ML2). This roughening treatment is performed in a state in which the plating film layer 122 fills the openings (RLa) of the resist layer (RL) formed on the metal film layer (ML2).

Next, the resist layer (RL) is removed, and, as illustrated in FIG. 3D, the upper surface of the metal film layer (ML2) is exposed. FIG. 3E illustrates a top view of the state illustrated in FIG. 3D, in which the upper surface of the metal film layer (ML2) and the upper surface of the plating film layer 122 are exposed. FIG. 3D illustrates a cross section along line D-D in FIG. 3E. In FIGS. 3D and 3E, the alignment pattern (AP) formed of the plating film layer 122 in the peripheral area (SA) has a central portion (C) having a circular planar shape, and a surrounding portion (P) having an annular planar shape that surrounds the central portion (C). In a gap portion (G) between the central portion (C) and the surrounding portion (P), the upper surface of the metal film layer (ML2) is exposed. The planar shape of the alignment pattern (AP) is not limited to the shape described above. For example, it is also possible that the alignment pattern (AP) has a cross-shaped planar shape formed by the plating film layer 122.

With reference to FIG. 3F, which is an enlarged view of a region (E) enclosed by a one-dot chain line in FIG. 3D, corresponding to a region (e) enclosed by a one-dot chain line in FIG. 3E, a surface state of the alignment pattern (AP) is described. The upper surface of the plating film layer 122 constituting the central portion (C) and the surrounding portion (P) has been subjected to the roughening treatment described above with reference to FIG. 3C. By this roughening treatment, as described above, the specular reflectance of light of a predetermined wavelength that can be detected by a device that images the alignment pattern (AP) differs between the upper surface of the plating film layer 122 (the central portion (C) and the surrounding portion (P)) and the upper surface of the metal film layer (ML2) (the gap portion (G)). For example, the specular reflectance of light of a predetermined wavelength that can be detected by a device that images the alignment pattern (AP) is 30% or more and 50% or less at the upper surface of the plating film layer 122, and is 60% or more at the upper surface of the metal film layer (ML2). Specifically, the upper surface of the plating film layer 122 can have a surface roughness of 0.35 μm or more and 0.6 μm or less in terms of arithmetic mean roughness, and the upper surface of the metal film layer (ML2) can have a surface roughness of 0.05 μm or more and less than 0.3 μm in terms of arithmetic mean roughness. The specular reflectance on the upper surface of the plating film layer 122 before the roughening treatment can be 60% or more.

Next, as illustrated in FIG. 3G, a first insulating layer 11 is laminated to cover the upper and side surfaces of the plating film layer 122, as well as the metal film layer (ML2) exposed from the conductor patterns of the plating film layer 122. As the first insulating layer 11, for example, an insulating resin such as an epoxy resin or a phenol resin can be used. A fluorine resin, a liquid crystal polymer (LCP), a fluoroethylene resin (PTFE), a polyester resin (PE), or a modified polyimide resin (MPI) also may be used. The first insulating layer 11 is formed by thermocompression bonding a resin molded into a film-like shape.

After the first insulating layer 11 is formed, a laser beam (LL), such as a carbon dioxide laser beam or UV laser beam, is irradiated to form through holes (11a) (see Fig. 3H) in the first insulating layer 11. A position at which the laser beam (LL) is irradiated onto the first insulating layer 11 is determined with reference to position information obtained from the alignment pattern (AP). Specifically, for example, the alignment pattern (AP) is imaged by a device (AC) that is an alignment camera equipped with coaxial illumination. Specular reflection light of a predetermined wavelength from the alignment pattern (AP) that transmits through the first insulating layer 11 is detected by the device (AC). The position information obtained from the imaged alignment pattern (AP) is referenced, and a position at which a through hole (11a) is to be formed (a position at which the laser beam (LL) is to be irradiated) is calculated.

As described above, since the upper surface of the plating film layer 122 is roughened, the specular reflectance of light detected by the device (AC) differs between the upper surface of the central portion (C) and surrounding portion (P) and the upper surface of the gap portion (G). As a result, in the image of the imaged alignment pattern (AP), brightness of the central portion (C) and surrounding portion (P) and brightness of the gap portion (G) have high contrast. In particular, as described above, when the plating film layer 122 has a relatively thin thickness of about 3 μm or more and 6 μm or less, or when the plating film layer 122 is formed of the same material as the material constituting the metal film layer (ML2), it is difficult for a difference to appear between the brightness of the central portion (C) and surrounding portion (P) and the brightness of the gap portion (G). In such a case, a high brightness contrast is effectively obtained by roughening the upper surface of the plating film layer 122. Therefore, when the position information is obtained from the imaged alignment pattern (AP), a boundary between the gap portion (G) and the central portion (C) and a boundary between the gap portion (G) and the surrounding portion (P) are clearly recognized, and thus a center position of the alignment pattern (AP) can be recognized with high accuracy. Highly accurate position information is obtained. As a result, the laser beam (LL) is irradiated relatively accurately onto a position at which a through hole (11a) is to be formed.

Although not illustrated, the irradiation of the laser beam (LL) such as carbon dioxide laser beam may be performed by irradiating the laser beam (LL) while protecting the upper surface of the first insulating layer 11 by covering it with a protective film such as a polyethylene terephthalate (PET) film or a polyethylene naphthalate (PEN) film. The first insulating layer 11 can be formed to have a thickness of about 7 μm to 15 μm. From a point of view of accurately imaging the alignment pattern (AP), it is desirable that a shortest distance from the upper surface of the first conductor layer 12 (upper surface of the plating film layer 122) to the upper surface of the first insulating layer 11 be 10 μm or less.

As illustrated in FIG. 3H, the through holes (11a) are formed in the first insulating layer 11. The through holes (11a) can be formed to each have a diameter of 5 μm or more and 15 μm or less at the upper surface of the first insulating layer 11. By the irradiation of the laser beam (LL), which references the highly accurate position information described above, the through holes (11a) can be relatively accurately formed at positions where the first via conductors 13 are to be formed. The through holes (11a) can be formed such that a ratio of a depth of each through hole (11a) to a diameter of each through hole (11a) is about 0.5 or more and about 1.5 or less. Here, the “depth of each through hole (11a)” means a shortest distance between the upper surface of the first conductor layer 12 and the upper surface of the first insulating layer 11, and the “diameter of each through hole (11a)” means a distance between two farthest points on an outer periphery of the through hole (11a) in a plan view, at the upper surface of the first insulating layer 11.

After the formation of the through holes (11a), a desmear treatment may be performed. The desmear treatment can preferably be a dry desmear treatment using a plasma gas. The desmear treatment can also be performed while protecting the surface of the first insulating layer 11, with a protective film such as a PET film formed on the surface of the first insulating layer 111.

Next, as illustrated in FIG. 3I, the first via conductors 13 filling the through holes (11a), and the first conductor layer 12 on the first insulating layer 11, are formed. A metal film layer 121 is formed on inner walls of the through holes (11a) and on a surface of the first insulating layer 11 by electroless plating, sputtering, or the like. When a protective film is provided on the surface of the first insulating layer 11 during the formation of the through holes (11a) and/or during the desmear treatment, the protective film can be peeled off and removed before the formation of the metal film layer 121. Subsequently, by electrolytic plating using the metal film layer 121 as a power feeding layer, a plating film layer 122 is formed in openings of a resist layer formed on the metal film layer 121. The through holes (11a) are completely filled with the electrolytic plating film, and the first via conductors 13 are formed. The resist layer is removed using an alkaline stripping solution, and then, a portion of the metal film layer 121 that is not covered by the plating film layer 122 is removed by etching. As a result, as illustrated in FIG. 3I, a first conductor layer 12 having a two-layer structure including the metal film layer 121 and the plating film layer 122, and having wirings (FW), is formed. The wirings (FW) can be formed such that a minimum wiring width is 2 μm or less and a minimum inter-wiring distance is 2 μm or less. As illustrated, the first conductor layer 12 is formed so as to include an alignment pattern (AP) in the peripheral area (SA), similar to the first conductor layer 12 formed in contact with the first support substrate (SP1).

Next, as illustrated in FIG. 3J, using methods similar to the methods for forming the first insulating layer 11, the first conductor layer 12 and the first via conductors 13 described above with reference to FIG. 3I, a desired number of first insulating layers 11 and first conductor layers 12, as well as first via conductors 13 penetrating the respective first insulating layers 11, are formed. In forming the through holes (11a) for forming the first via conductors 13, position information obtained from the alignment pattern (AP) covered by the insulating layer 11 in which the through holes (11a) are formed is referenced. The formation of the first build-up part 10 on the first surface (SP1a) of the first support substrate (SP1) is completed.

Next, as illustrated in FIG. 3K, on the uppermost first insulating layer 11 and first conductor layer 12 in the first build-up part 10, the lowermost second insulating layer 21 of the second build-up part 20 (see FIG. 3N) is laminated. The second insulating layer 21 can have a thickness that differs from that of each of the first insulating layers 11 constituting the first build-up part 10. For example, the second insulating layer 21 can be formed to have a thickness of about 20 μm to 30 μm. The second insulating layer 21 can be formed of an insulating resin similar to that constituting the first insulating layers 11. On the second insulating layer 21, a film (21F) formed of a resin such as PET, which is peelably adhered to the second insulating layer 21, is laminated.

Next, as illustrated in FIG. 3L, a pair of first build-up parts 10, each provided with a second insulating layer 21 and a film (21F), are bonded to two main surfaces (surfaces orthogonal to a thickness direction) of a second support substrate (SP2) via respective first support substrates (SP1). Each main surface of the second support substrate (SP2) and the second surface (SP1b) of each first support substrate (SP1) are bonded via an adhesive layer (ALC) constituted by any adhesive. The second support substrate (SP2) can be, for example, a glass substrate, a ceramic substrate, or a silicon substrate, similar to the core material (GS1) of the first support substrate (SP1).

Next, as illustrated in FIG. 3M, the second via conductors 23 penetrating the second insulating layer 21 and a second conductor layer 22 in contact with the upper surface of the second insulating layer 21 are formed. The film (21F) is peeled off from the second insulating layer 21. Subsequently, through holes (21a) are formed in the second insulating layer 21, for example, by laser irradiation, and a so-called semi-additive method is used to form the second via conductors 23 and the second conductor layer 22 on the second insulating layer 21, each having a two-layer structure including a metal film layer 221 and a plating film layer 222. The second conductor layer 22 can be formed to have a thickness of, for example, about 10 μm to 15 μm.

In FIG. 3M, as well as in FIGS. 3N-3R to be referenced below, the laminate formed on the surface on one side of the second support substrate (SP2) is illustrated, and illustration of the laminate that can be formed on the surface on the opposite side is omitted. However, on the surface on the opposite side of the second support substrate (SP2), a laminate of the form and number illustrated is also formed at the same time.

Therefore, warping is unlikely to occur in the process described with reference to FIGS. 3M to 3P.

Next, as illustrated in FIG. 3N, by repeating the above-described processes of forming the second insulating layer 21, the second conductor layer 22, and the second via conductor 23, a desired number of second insulating layers 21 and second conductor layers 22, as well as second via conductors 23 penetrating the respective second insulating layers 21, are formed. The formation of the second build-up part 20 on the first build-up part 10 is completed. In FIG. 3N, as well as in the following FIGS. 30 to 3R, the metal film layers (121, 221) and plating film layers (122, 222) are not depicted, and the conductor layers (12, 22) are depicted as each having a single-layer structure, similar to that in FIG. 1.

Next, as illustrated in FIG. 30, on the uppermost second insulating layer 21 and second conductor layer 22 of the second build-up part 20, the third insulating layers 31, the third conductor layers 32, and the third via conductors 33 penetrating the third insulating layers 31, of the third build-up part 30, are formed using methods similar to those used for forming the second insulating layers 21, the second conductor layers 22, and the second via conductors 23. As an insulating resin for forming the third insulating layers 31, a prepreg containing an insulating resin such as an epoxy resin or a BT resin impregnated into a reinforcing material (core material) composed of glass fiber can be used. As illustrated, the third build-up part 30 including two third insulating layers 31 and two third conductor layers 32 is formed.

Next, as illustrated in FIG. 3P, the first to third build-up parts (10, 20, 30) in the product area (MA) are separated from the laminate in the peripheral area (SA). For example, a groove (V) reaching the core material (GS1) of the first support substrate (SP1) is formed along a periphery of the product area (MA) by laser irradiation. When multiple product areas (MA) are included on the first support substrate (SP1), grooves (V) are also formed at boundaries between adjacent product areas (MA), and the first to third build-up parts (10, 20, 30) are divided for each product area (MA).

Next, as illustrated in FIG. 3Q, the first support substrate (SP1) and the second support substrate (SP2) are removed from the laminate in the product area (MA). In the removal of the first support substrate (SP1), the second metal film layer (ML2) of the first support substrate (SP1) is separated from the adhesive layer (AL1). The second metal film layer (ML2) and the adhesive layer (AL1) are relatively strongly bonded in the peripheral area (SA), and relatively weakly bonded in the product area (MA). Therefore, when the laminate in the product area (MA), separated from the peripheral area (SA), is lifted upward, the second metal film layer (ML2) is separated from the adhesive layer (AL1), as illustrated. The lower surface of the second metal film layer (ML2) beneath the conductor pad (12p) is exposed. Although not illustrated in FIG. 3Q, the removal of the first support substrate (SP1) is also similarly carried out on the side of the second support substrate (SP2) opposite to the side illustrated.

Next, the second metal film layer (ML2) is removed by etching, thereby exposing the lower surfaces of the conductor pads (12p) and the lower surface of the first insulating layer (11). Subsequently, as illustrated in FIG. 3R, the solder resist layer (SR1) is formed by forming a photosensitive epoxy resin or polyimide resin layer on the surfaces of the first insulating layer (11) and the first conductor layer (12). The openings (SR1a) exposing the conductor pads (12p) are formed in the solder resist layer (SR1) by photolithography. The solder resist layer (SR2) is formed by forming a photosensitive epoxy resin or polyimide resin layer on the surfaces of the insulating layer (31) and the conductor layer (32). The openings (SR2a) exposing the conductor pads (32p) are formed in the solder resist layer (SR2) by photolithography. The conductor bumps (BP) are formed on the conductor pads (12p) exposed in the openings (SR1a) of the solder resist layer (SR1). A plating layer including a nickel layer and a tin layer may be formed on the surfaces of the conductor bumps (BP). As illustrated in FIG. 3R, the wiring substrate 1 is completed.

Japanese Patent Laid-Open Publication No. 2012-9606 describes a method for manufacturing a wiring substrate. In the method for manufacturing a wiring substrate described in Japanese Patent Laid-Open Publication No. 2012-9606, a resist layer having an opening is formed on a support, which is, for example, a copper foil, and a first wiring layer is formed in the opening of the resist layer. After the first wiring layer is formed, the resist layer is removed, and a first insulating layer is formed on the first wiring layer and on the copper foil exposed from a pattern of the first wiring layer. A via hole is then formed in the first insulating layer by laser processing, and a via wiring is formed in the via hole.

In the method for manufacturing a wiring substrate described in Japanese Patent Laid-Open Publication No. 2012-9606, it is thought that the via hole may not always be formed with sufficient accuracy at a position in the first insulating layer where the via hole is to be formed.

A method for manufacturing a wiring substrate according to an embodiment of the present invention includes: preparing a support substrate having a metal film layer formed on a surface thereof; forming a plating film layer including an alignment pattern on the metal film layer; forming an insulating layer that covers the plating film layer; forming a through hole penetrating the insulating layer in a thickness direction by irradiating the insulating layer with a laser beam while referencing position information obtained from the alignment pattern; and forming a via conductor by filling the through hole with a conductor. The forming of the plating film layer includes causing a specular reflectance of light of a predetermined wavelength at an upper surface of the metal film layer to differ from that at an upper surface of the plating film layer.

According to an embodiment of the present invention, the specular reflectance of light of a predetermined wavelength at the upper surface of the metal film layer differs from that at the upper surface of the plating film layer. Therefore, the alignment pattern can be more precisely recognized, and thus, accurate position information can be obtained. A wiring substrate having via conductors formed at more accurate positions can be provided.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
preparing a support substrate having a metal film layer formed on a surface thereof;
forming a plating film layer including an alignment pattern on the metal film layer formed on the support substrate;
forming an insulating layer such that the insulating layer covers the plating film layer formed on the metal film layer;
irradiating the insulating layer with laser based on position information obtained from the alignment pattern in the plating film such that a through hole penetrating through the insulating layer is formed; and
filling the through hole formed in the insulating layer with a conductor such that a via conductor is formed in the insulating layer,
wherein the forming of the plating film layer includes causing a specular reflectance of light of a predetermined wavelength at an upper surface of the metal film layer formed on the support substrate to differ from a specular reflectance of light of the predetermined wavelength at an upper surface of the plating film layer.

2. The method for manufacturing a wiring substrate according to claim 1, wherein the forming of the plating film layer includes roughening the upper surface of the plating film layer.

3. The method for manufacturing a wiring substrate according to claim 2, wherein the roughening of the upper surface of the plating film includes roughening the upper surface of the plating film in a state in which the plating film layer fills openings formed in a resist layer formed on the metal film layer.

4. The method for manufacturing a wiring substrate according to claim 2, wherein the upper surface of the plating film layer is roughened such that the specular reflectance of light of the predetermined wavelength is in a range of 30% to 50%.

5. The method for manufacturing a wiring substrate according to claim 4, wherein the upper surface of the plating film layer is roughened to have an arithmetic mean roughness in a range of of 0.35 μm to 0.6 μm.

6. The method for manufacturing a wiring substrate according to claim 4, wherein the upper surface of the metal film layer is formed such that the specular reflectance of light of the predetermined wavelength is 60% or more.

7. The method for manufacturing a wiring substrate according to claim 1, wherein the position information is obtained by detecting light of the predetermined wavelength with a device that images the alignment pattern.

8. The method for manufacturing a wiring substrate according to claim 1, wherein the metal film layer and the plating film layer are formed of a same material.

9. The method for manufacturing a wiring substrate according to claim 1, wherein the plating film layer is formed to have a thickness in a range of 3 μm to 6 μm.

10. The method for manufacturing a wiring substrate according to claim 1, wherein the through hole is formed to have a diameter in a range of 5 μm to 15 μm at an upper surface of the insulating layer.

11. The method for manufacturing a wiring substrate according to claim 3, wherein the forming of the opening in the resist layer includes exposing the resist layer by direct imaging exposure.

12. The method for manufacturing a wiring substrate according to claim 11, wherein the surface of the support substrate includes at least one product area having a rectangular shape with each side measuring in a range of 80 mm to 240 mm, and the plating film layer and the insulating layer are formed over the at least one product area.

13. The method for manufacturing a wiring substrate according to claim 1, wherein the support substrate includes one of a glass substrate, a ceramic substrate and a silicon substrate.

14. The method for manufacturing a wiring substrate according to claim 2, wherein the position information is obtained by detecting light of the predetermined wavelength with a device that images the alignment pattern.

15. The method for manufacturing a wiring substrate according to claim 2, wherein the metal film layer and the plating film layer are formed of a same material.

16. The method for manufacturing a wiring substrate according to claim 2, wherein the plating film layer is formed to have a thickness in a range of 3 μm to 6 μm.

17. The method for manufacturing a wiring substrate according to claim 2, wherein the through hole is formed to have a diameter in a range of 5 μm to 15 μm at an upper surface of the insulating layer.

18. The method for manufacturing a wiring substrate according to claim 2, wherein the support substrate includes one of a glass substrate, a ceramic substrate and a silicon substrate.

19. The method for manufacturing a wiring substrate according to claim 3, wherein the position information is obtained by detecting light of the predetermined wavelength with a device that images the alignment pattern.

20. The method for manufacturing a wiring substrate according to claim 3, wherein the metal film layer and the plating film layer are formed of a same material.
